(19) United States
(12) Patent Application Publication
(10) Pub. No.: US 2021/0249390 A1
(43) Pub. Date: Aug. 12, 2021

(54) OPTOELECTRONIC SEMICONDUCTOR COMPONENT AND METHOD OF MANUFACTURING AN OPTOELECTRONIC SEMICONDUCTOR COMPONENT

(71) Applicant: OSRAM OLED GmbH, Regensburg (DE)

(72) Inventor: Andreas REITH, Steinach (DE)

(21) Appl. No.: 16/973,711

(22) PCT Filed: Jul. 4, 2019
(86) PCT No.: PCT/EP2019/067998

§ 371 Date: Dec. 9, 2020

(30) Foreign Application Priority Data
Jul. 12, 2018 (DE) 102018116928.0

(51) Int. Cl. H01L 25/16; H01L 33/48; H01L 33/00; H01L 33/62

(52) U.S. Cl. CPC H01L 25/167; H01L 33/486; H01L 2933/0066; H01L 33/62; H01L 33/005

(57) ABSTRACT

The invention relates to an optoelectronic semiconductor component (20) comprising a carrier comprising an integrated circuit, an optoelectronic semiconductor chip (22) which is arranged on the carrier (21), a molded body which surrounds the carrier at least in places in lateral directions and which covers the carrier in places on a side facing away from the optoelectronic semiconductor chip, and at least two through-connections which extend from an underside of the semiconductor component facing away from the optoelectronic semiconductor chip through the molded body to the carrier, and which comprise an electrically conductive material, the integrated circuit being provided for actuating and/or controlling the optoelectronic semiconductor chip. The invention also relates to a method of manufacturing an optoelectronic semiconductor component.

The invention relates to an optoelectronic semiconductor component and a method of manufacturing an optoelectronic semiconductor component.

One object of the invention is to specify an optoelectronic semiconductor component which can be operated efficiently. A further object is to specify a method of manufacturing an optoelectronic semiconductor component which can be operated efficiently.

According to at least one embodiment of the optoelectronic semiconductor component, the optoelectronic semiconductor component comprises a carrier comprising an integrated circuit. The carrier can be a three-dimensional body and can have the shape of a cylinder, a disk or a cuboid, for example. The carrier can have a main plane of extension. For example, the main extension plane of the carrier is parallel to a surface, for example a top surface, of the carrier. The carrier can comprise a semiconductor material. The integrated circuit can be an IC (integrated circuit) chip. For example, the carrier can have control electronics on or in a silicon substrate.

According to at least one embodiment of the optoelectronic semiconductor component, the optoelectronic semiconductor component comprises an optoelectronic semiconductor chip which is arranged on the carrier. The semiconductor chip is for example a luminescent diode chip, such as a light emitting diode chip or a laser diode chip, or a detector. This means that the optoelectronic semiconductor chip is designed to emit or detect electromagnetic radiation during operation. The optoelectronic semiconductor chip is arranged on a topside of the carrier.

According to at least one embodiment of the optoelectronic semiconductor component, the optoelectronic semiconductor component comprises a molded body which surrounds the carrier at least in places in lateral directions and which covers the carrier in places on a side facing away from the optoelectronic semiconductor chip. The lateral directions extend parallel to the main extension plane of the carrier. The molded body can be produced by means of a casting and/or injection process. These processes include all manufacturing processes in which a molding compound is introduced into a predetermined mold and, in particular, is subsequently hardened. In particular, the term casting process includes casting, injection molding, transfer molding and compression molding. Thus the molded body can be molded onto the carrier. The molded body can have a molding compound. The molded body can completely surround the carrier in lateral directions. On an underside of the carrier which faces away from the optoelectronic semiconductor chip, the molded body does not completely cover the carrier. The topside of the carrier facing the optoelectronic semiconductor chip can be free of the molded body.

According to at least one embodiment of the optoelectronic semiconductor component, the optoelectronic semiconductor component comprises at least two through-connections which extend from an underside of the semiconductor component facing away from the optoelectronic semiconductor chip through the molded body to the carrier, and which comprise an electrically conductive material. The through-connections can extend in a vertical direction, the vertical direction being perpendicular or transverse to the main extension plane of the carrier. The through-connections can be formed as recesses in the molded body, which are filled with electrically conductive material. The through-connections can be completely filled with the electrically conductive material. Alternatively, it is possible that the through-connections are only partially filled with the electrically conductive material. The electrically conductive material is copper, for example. The through-connections can be in direct contact with the molded body. Overall, the optoelectronic semiconductor component can have a plurality of through-connections.

According to at least one embodiment of the optoelectronic semiconductor component, the integrated circuit is intended for actuating and/or controlling the optoelectronic semiconductor chip. For this purpose the optoelectronic semiconductor chip can be electrically connected to the integrated circuit. For example, the optoelectronic semiconductor chip has electrical contacts on an underside of the optoelectronic semiconductor chip facing the carrier. The carrier can have electrical contacts on its topside. The optoelectronic semiconductor chip is electrically connected to the carrier via the electrical contacts. The integrated circuit is designed to actuate and/or control the optoelectronic semiconductor chip. For example, the integrated circuit can be designed to switch the optoelectronic semiconductor chip on and off. In addition, the integrated circuit is designed to control the power supply of the optoelectronic semiconductor chip.

According to at least one embodiment of the optoelectronic semiconductor component, the optoelectronic semiconductor component comprises a carrier comprising an integrated circuit, an optoelectronic semiconductor chip which is arranged on the carrier, a molded body which surrounds the carrier at least in places in lateral directions and which covers the carrier in places on a side facing away from the optoelectronic semiconductor chip, and at least two through-connections which extend from an underside of the semiconductor component facing away from the optoelectronic semiconductor chip through the molded body to the carrier and which comprise an electrically conductive material, the integrated circuit being provided for actuating and/or controlling the optoelectronic semiconductor chip.

The optoelectronic semiconductor component described here is based, among other things, on the idea that thermo-mechanical tensions can be relieved by means of the through-connections. In a semiconductor component, thermo-mechanical tensions can occur between different components that have different coefficients of thermal expansion. In particular, these tensions can already occur during the manufacturing process at large temperature changes. Thermo-mechanical tensions can lead to cracks in a semiconductor component and an overall reduction in the reliability of the semiconductor component. By using through-connections, less thermo-mechanical tension is transferred from the underside of the semiconductor component to the semiconductor chip, since this tension is relieved by a mechanical deformation of the through-connections. Since the through-connections comprise copper, for example, they have a high thermal conductivity. Thus, the insertion of the through-connections can lead to an increased lifetime of the semiconductor component.

The molded body can serve as a stable and cost-effective holding device for the semiconductor component. Since the carrier can be completely surrounded by the molded body in lateral directions, the carrier is protected by the molded body from external, for example mechanical or chemical, influences.

According to at least one embodiment of the optoelectronic semiconductor component, the optoelectronic semiconductor chip has a radiation passage side which faces away from the carrier. The radiation passage side is the side of the semiconductor chip where at least a large part of the electromagnetic radiation generated or to be received during operation exits the semiconductor chip or enters it. For example, the semiconductor chip is a radiation-emitting semiconductor chip and is designed to emit electromagnetic radiation in the direction of the radiation passage side. Thus, it is not necessary that the carrier or molded body be transparent to the electromagnetic radiation emitted by the semiconductor chip.

According to at least one embodiment of the optoelectronic semiconductor component, the optoelectronic semiconductor component has at least two through-connections. With a small number of through-connections a lower thermo-mechanical tension is built up in the semiconductor component, but the thermal resistance of the through-connections is higher than with a large number of through-connections. Thermo-mechanical tensions in the semiconductor component can be efficiently relieved by a plurality of through-connections.

According to at least one embodiment of the optoelectronic semiconductor component, the through-connections are completely filled with the electrically conductive material. The through-connections can be filled with the electrically conductive material from the underside of the semiconductor component. For example, the through-connections can be filled with the electrically conductive material by means of a plating process. This enables an efficient reduction of thermo-mechanical tensions in the semiconductor component.

According to at least one embodiment of the optoelectronic semiconductor component, the through-connections are not used to power the integrated circuit. This means that the through-connections are not electrical contacts for electrical contacting of the integrated circuit. The through-connections are exclusively thermal contacts, which can be used to relieve thermo-mechanical tensions.

According to at least one embodiment of the optoelectronic semiconductor component, at least two of the through-connections are used to power the integrated circuit. Thus, the integrated circuit can be controlled via the at least two through-connections. Advantageously, no further electrical connections are required for contacting the integrated circuit.

According to at least one embodiment of the optoelectronic semiconductor component, the through-connections are designed to relieve thermo-mechanical tensions. For this purpose, the through-connections can have a coefficient of thermal expansion which is different from the coefficient of thermal expansion of the material of the molded body. In particular, thermo-mechanical tensions can be relieved more efficiently via the through-connections than via a full-surface electrical contact of the carrier.

According to at least one embodiment of the optoelectronic semiconductor component, the molded body comprises an electrically insulating material. The electrically insulating material may in particular have a coefficient of thermal expansion which is different from the coefficient of thermal expansion of the electrically conductive material of the through-connections. This allows thermo-mechanical tensions in the semiconductor component to be efficiently relieved via the through-connections.

According to at least one embodiment of the optoelectronic semiconductor component, the underside of the semiconductor component is completely covered with the electrically conductive material between the through-connections. When filling the through-connections with the electrically conductive material, the electrically conductive material is also applied to the underside of the semiconductor component. The electrically conductive material on the underside of the semiconductor component is not removed between the through-connections. This means that the electrically conductive material on the underside is arranged over the entire surface of the carrier. Thermo-mechanical tensions in the semiconductor component can be relieved via the through-connections and the electrically conductive material which is arranged over the entire surface.

According to at least one embodiment of the optoelectronic semiconductor component, at least one further through-connection extends through the molded body from the underside of the semiconductor component to a topside facing away from the underside. The further through-connection extends completely through the molded body. This means that the further through-connection is completely surrounded by the molded body in lateral directions. The further through-connection can extend in vertical direction. The semiconductor component can have a total of two further through-connections. The two further through-connections can be arranged on different sides next to the carrier. The further through-connection can be intended for the electrical contacting of the carrier.

According to at least one embodiment of the optoelectronic semiconductor component, at least one electrically conductive connection is arranged on the topside of the semiconductor component, said connection running from the further through-connection to the carrier. The electrically conductive connection can comprise an electrically conductive material. The electrically conductive material can be applied to the topside of the semiconductor component. In this case the electrically conductive material extends on the topside of the semiconductor component from the further through-connection to the carrier. The electrically conductive material can be connected to an electrical contact of the carrier. If the semiconductor component has two further through-connections, two electrically conductive connections are arranged on the topside of the semiconductor component. The electrically conductive connection and the further through-connection are intended for the electrical contacting of the carrier.

According to at least one embodiment of the optoelectronic semiconductor component, the optoelectronic semiconductor component has at least two electrical contacts for contacting the optoelectronic semiconductor chip on the underside of the semiconductor component. Each of the electrical contacts on the underside of the semiconductor component is electrically connected to a further through-connection. The electrical contacts can comprise an electrically conductive material which is applied to the underside of the semiconductor component. The electrical contacts are spaced apart from the electrically conductive material on the underside of the semiconductor component, which is arranged in the area of the carrier. The electrical contacts are electrically conductively connected to the carrier via the further through-connections and the electrically conductive connections. The carrier is electrically conductively connected to the semiconductor chip and designed to actuate it. Thus, the semiconductor chip can be electrically contacted via the electrical contacts on the underside of the semiconductor component and the carrier. Therefore the semiconductor component is advantageously surface-mountable.

According to at least one embodiment of the optoelectronic semiconductor component, the through-connections are electrically insulated from the optoelectronic semiconductor chip. Since the through-connections are only thermal contacts, they are not electrically conductively connected to the semiconductor chip. For example, an electrically insulating layer can be arranged in the carrier between the through-connections and electrically conductive areas of the carrier. This has the advantage that less thermo-mechanical tension is transferred to the semiconductor chip.

The invention further relates to a method of manufacturing an optoelectronic semiconductor component. The optoelectronic semiconductor component can preferably be manufactured by a method described here. In other words, all features disclosed for the optoelectronic semiconductor component are also disclosed for the method of manufacturing an optoelectronic semiconductor component and vice versa.

According to at least one embodiment of the method of manufacturing an optoelectronic semiconductor component, the method comprises a method step in which a carrier is provided which comprises an integrated circuit and on which an optoelectronic semiconductor chip is arranged. The semiconductor chip can, for example, be connected to the carrier by means of an adhesive bond or a solder joint.

According to at least one embodiment of the method of manufacturing an optoelectronic semiconductor component, the method comprises a method step in which a molded body is molded around the carrier, said molded body surrounding the carrier at least in places in lateral directions and covering the carrier at least in places on a side facing away from the optoelectronic semiconductor chip. The molded body can completely cover the carrier in lateral directions. Furthermore, the molded body can completely cover the carrier on the side facing away from the optoelectronic semiconductor chip. The carrier can be in direct contact with the molded body. A topside of the carrier facing the semiconductor chip can be free of the molded body. To protect the topside of the carrier and the semiconductor chip, a protective layer or a protective film can be arranged on the topside of the carrier while the molded body is molded around the carrier.

According to at least one embodiment of the method of manufacturing an optoelectronic semiconductor component, the method comprises a method step in which at least two recesses are created in the molded body, which extend from the underside of the optoelectronic semiconductor component to the carrier. The recesses are thus arranged below the carrier. The recesses can extend in vertical direction. It is also possible that a plurality of recesses are created in the molded body, which extend from the underside of the semiconductor component to the carrier. The recesses can for example be formed with a laser or mechanically. For this purpose, material of the molded body is removed in the recesses.

According to at least one embodiment of the method of manufacturing an optoelectronic semiconductor component, the method comprises a method step in which an electrically conductive material is deposited in the recesses and on the underside of the optoelectronic semiconductor component so that through-connections are formed. The electrically conductive material can be deposited by a plating process, for example. The electrically conductive material can completely fill the recesses. Furthermore, the electrically conductive material can completely cover the underside of the semiconductor component. Each recess filled with the electrically conductive material forms a through-connection.

According to at least one embodiment of the method of manufacturing an optoelectronic semiconductor component, the integrated circuit is provided for actuating and/or controlling the optoelectronic semiconductor chip.

The method described here is based, among other things, on the idea that an optoelectronic semiconductor component is produced in which thermo-mechanical tensions can be relieved via the through-connections. During the process of manufacturing the semiconductor component, large temperature differences can occur. These can lead to thermo-mechanical tensions in the semiconductor component if the coefficients of thermal expansion of different materials of the semiconductor component are different. For example, during the assembly of the semiconductor component on a circuit board, for example by soldering, thermo-mechanical tensions can occur due to the different coefficients of thermal expansion of the materials. These tensions can be relieved via the through-connections.

According to at least one embodiment of the method of manufacturing an optoelectronic semiconductor component, the molded body is produced by means of a casting and/or injection process. These processes include all manufacturing processes in which a molding compound is introduced into a predetermined mold and, in particular, is subsequently hardened. The term casting process includes all manufacturing processes in which a molding compound is introduced into a predetermined mold and, in particular, is subsequently hardened. In particular, the term casting process includes casting, injection molding, transfer molding and compression molding. Thus the molded body can be molded onto the carrier. For this purpose, the carrier with the semiconductor chip can be placed in a mold which is arranged on the topside and the underside of the carrier. To protect the semiconductor chip, a protective film can be attached to the topside of the carrier. A molded body produced in this way can serve as a cost-effective and stable holding device for the carrier with the semiconductor chip.

According to at least one embodiment of the method of manufacturing an optoelectronic semiconductor component, at least two electrical contacts for contacting the optoelectronic semiconductor chip are formed on the underside of the optoelectronic semiconductor component. For this purpose, the electrically conductive material applied over the entire surface can be removed in places from the underside of the semiconductor component. For example, the electrically conductive material can be removed by etching. The electrically conductive material is removed from the underside of the semiconductor component in such a way that at least two spaced areas of the electrically conductive material remain on the underside. These at least two areas form the electrical contacts. In addition, the electrically conductive material on the underside remains in the area of the carrier. Advantageously, the semiconductor component is thus surface-mountable.

According to at least one embodiment of the method of manufacturing an optoelectronic semiconductor component, at least one further through-connection is formed which extends from the underside of the optoelectronic semiconductor component to a topside facing away from the underside. For this purpose, a recess can be formed in the molded body, which extends from the underside of the semiconductor component to the topside. The recess can be completely filled with an electrically conductive material. In total, at least two further through-connections can be formed. The two further through-connections can be arranged on different sides next to the carrier. Each of the further through-connections can be electrically conductively connected to one of the electrical contacts on the underside of the semiconductor component. Thus, the further through-connections form electrical connections to the topside of the semiconductor component.

According to at least one embodiment of the method of manufacturing an optoelectronic semiconductor component, electrically conductive material is applied to a topside facing away from the underside of the optoelectronic semiconductor component for contacting the optoelectronic semiconductor chip. The electrically conductive material can be applied to the entire surface of the topside of the semiconductor component. Meanwhile, the semiconductor chip can be covered with a protective film or layer so that it is not covered with the electrically conductive material. The electrically conductive material applied to the entire surface can be removed from the topside in places. For example, the electrically conductive material can be removed by etching. This allows electrical connections to be formed between the further through-connections and the carrier. For example, one electrical connection can extend from each further through-connection to the carrier and make electrical contact with it. Thus, the carrier and thus also the semiconductor chip can be electrically contacted via the electrical contacts on the underside of the semiconductor component, the further through-connections and the electrical connections on the topside of the semiconductor component.

In the following, the optoelectronic semiconductor component described here and the method of manufacturing an optoelectronic semiconductor component described here are explained in more detail in conjunction with exemplary embodiments and the associated figures.

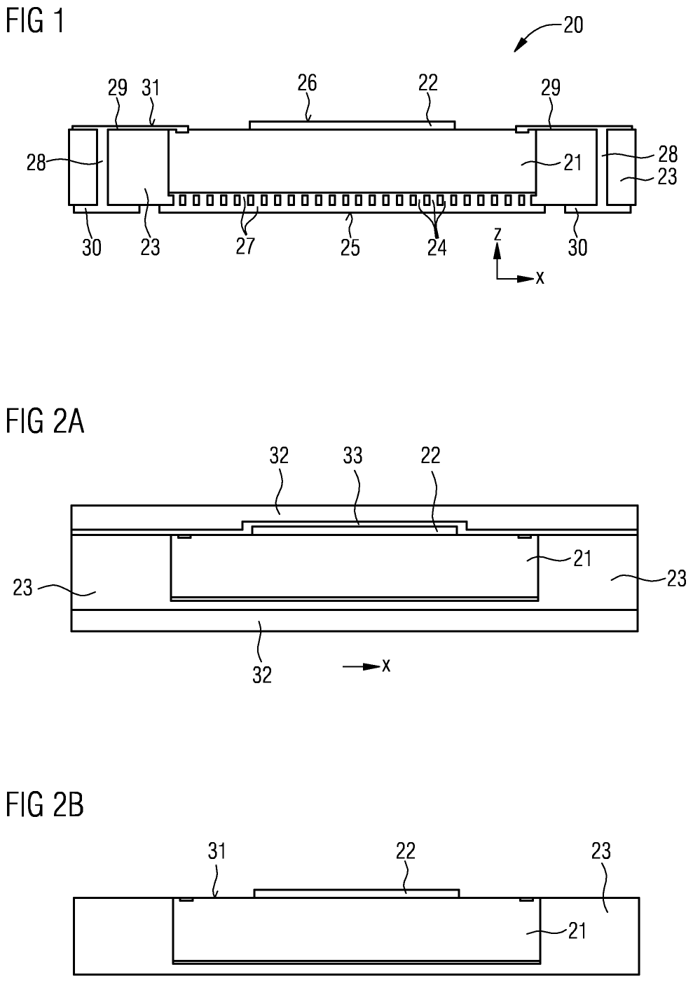

FIG. 1 shows a schematic cross-section of an optoelectronic semiconductor component according to an exemplary embodiment.

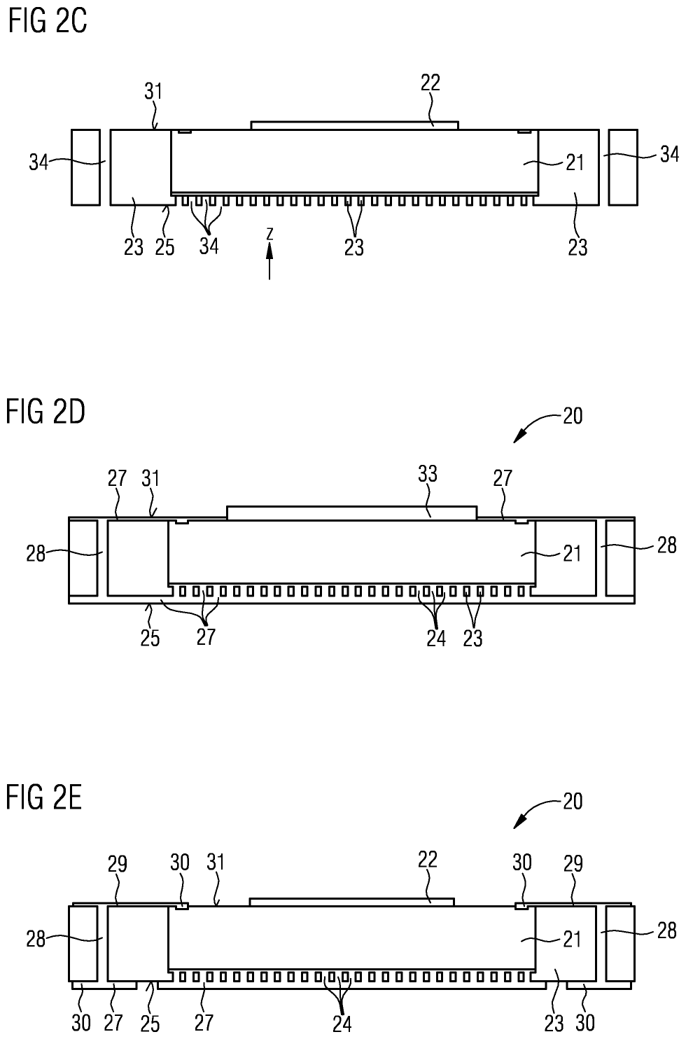

In connection with FIGS. 2A, 2B, 2C, 2D and 2E an exemplary embodiment of the method of manufacturing an optoelectronic semiconductor component is described.

Identical, similar or equivalent elements are provided with the same reference signs in the figures. The figures and the proportions of the elements represented in the figures among each other are not to be considered as true to scale. Rather, individual elements may be oversized for better representability and/or for better comprehensibility.

FIG. 1 shows a schematic cross-section of an exemplary embodiment of an optoelectronic semiconductor component 20. The semiconductor component 20 has a carrier 21, which comprises an integrated circuit. An optoelectronic semiconductor chip 22 is arranged on the carrier 21. The semiconductor chip 22 is designed to emit electromagnetic radiation during operation. The semiconductor chip 22 has a radiation passage side 26, which faces away from the carrier 21. The integrated circuit of the carrier 21 is provided for actuating and/or controlling the semiconductor chip 22.

The semiconductor component 20 further comprises a molded body 23, which surrounds the carrier 21 in lateral directions x. The lateral directions x are parallel to a main extension plane of the carrier 21. The molded body 23 completely surrounds the carrier 21 in lateral directions x. On an underside 25 of the carrier 21 facing away from the semiconductor chip 22, the molded body 23 covers the carrier 21 in places. The molded body 23 comprises an electrically insulating material. A plurality of through-connections 24 extend through the molded body 23 from an underside 25 of the semiconductor component 20 facing away from the semiconductor chip 22 to the carrier 21. The through-connections 24 extend in a vertical direction z, the vertical direction z being perpendicular to the main extension plane of the carrier 21. The through-connections 24 comprise an electrically conductive material 27 and are completely filled with it. On the underside 25 of the semiconductor component 20, an electrically conductive material 27 is arranged over the entire area of the carrier 21. The electrically conductive material 27 on the underside 25 of the semiconductor component 20 is in direct contact with the through-connections 24, which means that the underside 25 of the semiconductor component 20 is completely covered with the electrically conductive material 27 between the through-connections 24.

The through-connections 24 are only thermal contacts. The through-connections 24 are not used to power the integrated circuit of the carrier 21. Since the thermal expansion coefficient of the electrically conductive material 27 is different from that of the electrically insulating material of the molded body 23, thermo-mechanical tensions that occur in the semiconductor component 20 or during the assembly of the semiconductor component 20 can be relieved via the through-connections 24.

Two further through-connections 28 extend through the molded body 23 from the underside 25 of the semiconductor component 20 to a topside 31 of the semiconductor component 20 facing away from the underside 25. The further through-connections 28 are also completely filled with the electrically conductive material 27. The further through-connections 28 extend in vertical direction z. In lateral direction x the further through-connections 28 are arranged on different sides next to the carrier 21.

Two electrical contacts 30 for contacting the semiconductor chip 22 are arranged on the underside 25 of the semiconductor component 20. The electrical contacts 30 comprise an electrically conductive material 27, which is arranged on the underside 25 of the semiconductor component 20. Each of the electrical contacts 30 is electrically connected to a further through-connection 28. Two electrically conductive connections 29 are arranged on the topside 31 of the semiconductor component 20. Each of the electrically conductive connections 29 is electrically conductively connected to a further through-connection 28. In addition, each of the electrically conductive connections 29 extends from a further through-connection 28 to the carrier 21.

The carrier 21 has electrical contacts 30 on a topside 31 facing the semiconductor chip 22. The electrical contacts 30 are electrically conductively connected to the electrically conductive connections 29. The semiconductor chip 22 can be controlled via the carrier 21. Since the carrier 21 can be electrically contacted via the electrically conductive connections 29, the further through-connections 28 and the electrical contacts 30, the semiconductor chip 22 can also be electrically contacted via the electrical contacts 30 on the underside 25 of the semiconductor component 20.

However, the semiconductor chip 22 is electrically insulated from the through-connections 24, which only provide a thermal connection to the carrier 21.

FIG. 2A shows a step of the method of manufacturing an optoelectronic semiconductor component 20 according to an exemplary embodiment. A schematic cross-section of the carrier 21 with the semiconductor chip 22 is shown. According to one embodiment of the method, the carrier 21 is provided, on which the optoelectronic semiconductor chip 22 is arranged. The molded body 23 is molded around the carrier 21. For this purpose, the carrier 21 with the semiconductor chip 22 is placed in a mold 32. To protect the semiconductor chip 22, a protective film 33 is arranged between the semiconductor chip 22 and the mold 32. The molded body 23 is thus produced by means of a casting and/or injection process. The molded body 23 is molded around the carrier 21 in such a way that it completely covers the carrier 21 in lateral directions x and on the underside 25.

FIG. 2B shows that in a next step of the method the mold 32 and the protective film 33 are removed. The topside 31 of the carrier 21 is free of the molded body 23.

FIG. 2C shows that in a next step of the method a plurality of recesses 34 are created in the molded body 23. The recesses 34 extend from the underside 25 of the semiconductor component 20 to the carrier 21. The recesses 34 can be formed for example with a laser or mechanically. In addition, two further recesses 34 are formed, which extend from the underside 25 of the semiconductor component 20 to the topside 31 of the semiconductor component 20. These further recesses 34 can also be formed with a laser or mechanically. The recesses 34 extend in vertical direction z.

FIG. 2D shows that in a next step of the method the electrically conductive material 27 is deposited in the recesses 34. The electrically conductive material 27 is applied on the underside 25 of the semiconductor component 20. After deposition of the electrically conductive material 27, the underside 25 of the semiconductor component 20 is completely covered with the electrically conductive material 27. By filling the recesses 34, through-connections 24 are formed which extend from the underside 25 of the semiconductor component 20 to the carrier 21. In addition, by filling up the two further recesses 34, two further through-connections 28 are formed, which extend from the underside 25 of the semiconductor component 20 to the topside 31 of the semiconductor component 20. The electrically conductive material 27 is also deposited on the topside 31 of the semiconductor component 20. To protect the semiconductor chip 22, a protective film 33 is arranged on the semiconductor chip 22. The electrically conductive material 27 can be deposited over the entire surface of the topside 31 of the semiconductor component 20.

FIG. 2E shows that in a next step of the method two electrical contacts 30 for contacting the semiconductor chip 22 are formed on the underside 25 of the semiconductor component 20. For this purpose, the electrically conductive material 27 is partially removed from the underside 25 of the semiconductor component 20, for example by etching. The two electrical contacts 30 are arranged at a distance from each other. Each of the electrical contacts 30 is electrically conductively connected to one of the further through-connections 28. Furthermore, a complete coverage of the underside 25 of the semiconductor component 20 with the electrically conductive material 27 remains in the area of the carrier 21. Thus, the underside 25 of the semiconductor component 20 is completely covered with the electrically conductive material 27 between the through-connections 24.

On the topside 31 of the semiconductor component 20, the electrically conductive material 27 is removed in places, so that an electrically conductive connection 29 is formed from each further through-connection 28 to the carrier 21. The carrier 21 has two electrical contacts 30 on its topside 31. The electrical contacts 30 are each electrically connected to one of the electrically conductive connections 29. The semiconductor chip 22 can thus be electrically contacted via the carrier 21, the electrically conductive connections 29, the further through-connections 28 and the electrical contacts 30.

This patent application claims the priority of German patent application 102018116928.0, the disclosure content of which is hereby incorporated by reference.

The invention is not limited to the exemplary embodiments based on the description of the same. Rather, the invention comprises any new feature as well as any combination of features, which in particular includes any combination of features in the claims, even if this feature or this combination itself is not explicitly stated in the claims or exemplary embodiments.

### LIST OF REFERENCE SIGNS

20: semiconductor component
21: carrier
22: semiconductor chip
23: molded body
24: through-connection
25: underside
26: radiation passage side
27: electrically conductive material
28: further through-connection
29: electrically conductive connection
30: electrical contact
31: topside
32: mold
33: protective film
34: recess
x: lateral direction
z: vertical direction

1. An optoelectronic semiconductor component comprising:
a carrier comprising an integrated circuit,
an optoelectronic semiconductor chip which is arranged on the carrier,
a molded body which surrounds the carrier at least in places in lateral directions and which covers the carrier in places on a side facing away from the optoelectronic semiconductor chip, and
at least two through-connections which extend from an underside of the semiconductor component facing away from the optoelectronic semiconductor chip through the molded body to the carrier, and which comprise an electrically conductive material, the integrated circuit being provided for actuating and/or controlling the optoelectronic semiconductor chip.

2. The optoelectronic semiconductor component according to claim 1, in which the optoelectronic semiconductor chip has a radiation passage side which faces away from the carrier.

3. The optoelectronic semiconductor component according to claim 1, which has at least two through-connections.

4. The optoelectronic semiconductor component according to claim 1, in which the through-connections are completely filled with the electrically conductive material.

5. The optoelectronic semiconductor component according to claim 1, in which the through-connections are not used to power the integrated circuit.

6. The optoelectronic semiconductor component according to claim 1, in which the through-connections are configured to relieve thermo-mechanical tensions.

7. The optoelectronic semiconductor component according to claim 1, in which the molded body comprises an electrically insulating material.

8. The optoelectronic semiconductor component according to claim 1, in which the underside of the semiconductor component is completely covered with the electrically conductive material between the through-connections.

9. The optoelectronic semiconductor component according to claim 1, in which at least one further through-connection extends through the molded body from the underside of the semiconductor component to a topside facing away from the underside.

10. The optoelectronic semiconductor component according to claim 9, in which at least one electrically conductive connection is arranged on the topside of the semiconductor component, said connection running from the further through-connection to the carrier.

11. The optoelectronic semiconductor component according to claim 1, which has at least two electrical contacts for contacting the optoelectronic semiconductor chip on the underside of the semiconductor component.

12. The optoelectronic semiconductor component according to claim 1, in which the through-connections are electrically insulated from the optoelectronic semiconductor chip.

13. A method of manufacturing an optoelectronic semiconductor component comprising the steps of:
providing a carrier which comprises an integrated circuit and on which an optoelectronic semiconductor chip is arranged,
molding a molded body around the carrier, said molded body surrounding the carrier at least in places in lateral directions and covering the carrier at least in places on a side facing away from the optoelectronic semiconductor chip,
creating at least two recesses in the molded body, which extend from the underside of the optoelectronic semiconductor component to the carrier, and
depositing an electrically conductive material in the recesses and on the underside of the optoelectronic semiconductor component so that through-connections are formed, wherein
the integrated circuit is provided for actuating and/or controlling the optoelectronic semiconductor chip.

14. The method according to the claim 13, in which the molded body is produced by means of a casting and/or injection process.

15. The method according to claim 13, in which at least two electrical contacts for contacting the optoelectronic semiconductor chip are formed on the underside of the optoelectronic semiconductor component.

16. The method according to claim 13, in which at least one further through-connection is formed which extends from the underside of the optoelectronic semiconductor component to a topside facing away from the underside.

17. The method according to claim 13, in which electrically conductive material is applied to a topside facing away from the underside of the optoelectronic semiconductor component for contacting the optoelectronic semiconductor chip.
